(19) United States
(12) Patent Application Publication
(10) Pub. No.: US 2012/0024178 A1
(43) Pub. Date: Feb. 2, 2012

(54) LEAD-FREE PRIMERS FOR HOT WIRE APPLICATIONS

(76) Inventors: John W. FRONABARGER, Sun Lakes, AZ (US); Michael D. WILLIAMS, Gilbert, AZ (US)

(21) Appl. No.: 13/194,147

(22) Filed: Jul. 29, 2011

Related U.S. Application Data
(60) Provisional application No. 61/368,896, filed on Jul. 29, 2010.

(51) Int. Cl. F42C 19/12; H05K 13/00; F42C 11/00

(52) U.S. Cl. 102/202.7; 29/592.1

(57) ABSTRACT

Described are hot-wire igniter devices comprising a bridgewire, an acceptor proximate a portion of the bridgewire, and an output configured to be ignited by the acceptor, wherein the acceptor comprises copper(I) 5-nitrotetrazole. The bridgewire may be configured to receive power from a power source. The bridgewire composition may comprise Tophet A, Tophet C, stainless steel, nichrome bridgewire materials, or stablohm bridgewire materials. The output may be an explosive, pyrotechnic, or propellant.

### CROSS REFERENCE TO RELATED APPLICATION

This invention claims the benefit of U.S. Provisional Patent Application Ser. No. 61/368,896, entitled “Lead-Free Primers for Hot Wire Applications,” filed Jul. 29, 2010, the entire contents of which are incorporated herein by this reference.

### STATEMENT OF GOVERNMENT SUPPORT

This invention was made in part with U.S. government support under Contract No. N00174-04-D-4149 awarded by the United States of America for the Department of the Navy. The government has certain rights in this invention.

### FIELD OF THE INVENTION

This invention relates to improved lead-free energetic compositions, which are suitable for use in hot-wire applications.

### BACKGROUND

Primary explosives are sensitive explosive materials that are used, in relatively small quantities, to initiate a secondary or main explosive charge. Primary explosives are used in percussion primers and electric primers (hot-wire igniters) to initiate an explosion. Hot-wire igniter systems, such as the system illustrated in FIG. 1, are commonly used in both military and commercial applications as a method of initiation, wherein application of current from a power source is used to heat a filament and the heat is transferred to a reactive material (acceptor) to provide energy sufficient to ignite an output.

A hot-wire igniter is generally composed of a filament or bridgewire of high resistance, which is situated inside a composition, which will ignite when a suitable current is applied. Common bridgewire materials are nichrome (Tophet A or C), which are composed of nickel, chromium and/or iron in various ratios, and stainless steel. These materials have high heat resistance and will withstand high temperatures (˜1400° C.) before melting. They can therefore easily and rapidly transfer this heat to an ignitable composition such as a pyrotechnic or explosive charge.

Common materials that serve as acceptors of the bridgewire energy are lead styphnate, normal (“NLS”) or basic (“BLS”), and a number of pyrotechnics, such as zirconium/potassium perchlorate (“ZPP”) and, more rarely, lead azide. In these cases, the heat transferred from the bridgewire exceeds the ignition temperature of the acceptor and is sufficient to cause deflagration (or detonation) of that material. The energy of this event may be used to further ignite a pyrotechnic, propellant or explosive output.

These acceptor materials may be undesirable from an environmental standpoint because their use and manufacture may contribute to or cause lead contamination. Thus, it may be desirable to provide a lead-free material that may be used as a drop-in replacement for these lead-containing acceptor materials in hot-wire igniter devices.

### SUMMARY

Embodiments of the present invention provide a hot-wire igniter device comprising a bridgewire, an acceptor proximate a portion of the bridgewire, and an output configured to be ignited by the acceptor, wherein the acceptor comprises copper(I) 5-nitrotetrazole. In some embodiments, the copper(I) 5-nitrotetrazole is substituted in place of normal lead styphnate, basic lead styphnate, zirconium/potassium perchlorate, or lead azide. In these embodiments, the acceptor may be free of lead.

The bridgewire may be configured to receive power from a power source. In these embodiments, the power may comprise a constant current or a constant voltage, and the power source may be a capacitor discharge. The bridgewire composition may comprise Tophet A, Tophet C, stainless steel, nichrome bridgewire materials, or stablohm bridgewire materials.

In some embodiments, the output is an explosive, pyrotechnic, or propellant. The output composition may comprise octahydro-1,3,5,7-tetranitro-1,3,5,7-tetrazocine, cyclotrimethylenetrinitramine, 2,6-Bis(Picrylamino)-3,5-dinitropyridine, or 2,4,6-trinitrotoluene.

### BRIEF DESCRIPTION OF THE DRAWINGS

FIG. 1 is a cross-sectional view of a hot-wire igniter device.

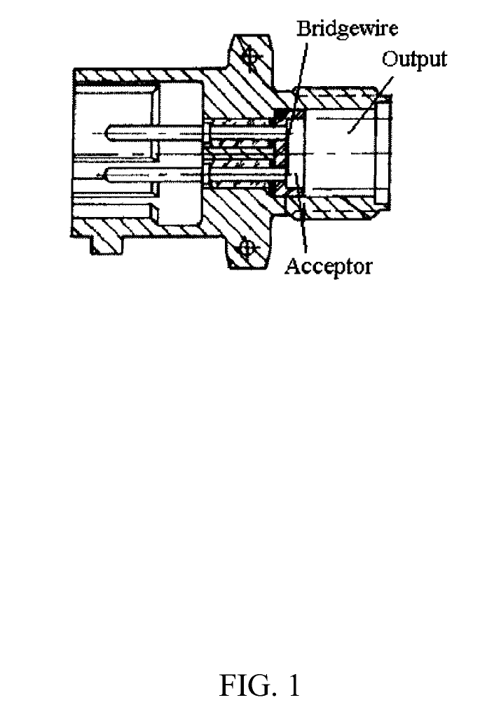

### DETAILED DESCRIPTION

Embodiments of the invention provide for application of copper(I) 5-nitrotetrazole (“DBX-1”) as a direct replacement for hot-wire acceptors. While the DBX-1 is discussed for use in hot-wire applications, it is by no means so limited. Rather, DBX-1 may be used as a replacement for lead azide or other similar lead-containing materials in other applications or otherwise as desired.

The composition and methods of preparation of copper(I) nitrotetrazolate is the subject of U.S. Pat. No. 7,833,330 and U.S. patent application Ser. Nos. 12/691,849 and 12/900,531, the entire contents of each of which are incorporated herein by these references.

In the current embodiment, DBX-1 is used as a direct replacement for other hot-wire acceptors including but not limited to normal lead styphnate, basic lead styphnate, zirconium/potassium perchlorate, or lead azide. While lead azide has not commonly been used as an acceptor in hot-wire applications, it has been successfully utilized in the M100 electric detonator, as well as a DOE dual ribbon bridge device. DBX-1 has been designed to be a drop-in replacement for lead azide (RD1333) as a transfer or output charge; however, testing has indicated that it may be suitable as a reliable hot-wire acceptor material.

Qualification testing (NAVSEAINST 8020.5C or NATO AOP-7) of DBX-1 involved aging samples of the material at 70° C. for one year and evaluating hot-wire initiation versus lead azide at various time periods during the aging process. These tests included both constant current and capacitor discharge initiation of P-12 units (BuOrd Drawing 1386180) containing 20 mg of test material pressed at 5 kpsi and bridged with either 0.0005″ or 0.001″ Nichrome (Tophet C) bridgewires. Common bridgewire materials include Tophet A, Tophet C, stainless steel, or other similar nichrome or stablohm type bridgewire materials.

Samples of aged (at 70° C.) DBX-1 were tested at 0, 6, and 12 months and compared to unaged samples of DBX-1 (ambient conditions for 1 year) and RD1333. Results are shown below in Table 1.

TABLE 1
Hot Wire Initiation Testing.

| | | | Constant Current | | | Cap. Discharge | |
|---|---|---|---|---|---|---|---|
| | | Bridge | Mean | AF 99.9% | NF 0.1% | Mean | Stored Energy |
| Material | Aging | Tophet C | (amps) | (amps) | (amps) | (volts, mf) | (mJ) |
| RD1333 | | 0.001 | 0.299 ± 0.009 | 0.326 | 0.272 | 79.99 ± 1.04, 1.0 | 3.20 |
| | | 0.0005 | 0.132 ± 0.008 | 0.157 | 0.108 | 143.55 ± 1.25, 0.1 | 1.03 |
| DBX-1 | T = 0 | 0.001 | 0.252 ± 0.017 | 0.304 | 0.201 | 77.62 ± 0, 1.0 | 3.01 |
| | | 0.0005 | 0.106 ± 0.005 | 0.121 | 0.092 | 122.89 ± 1.05, 0.1 | 0.76 |
| DBX-1 | T = 6 m | 0.001 | 0.244 ± 0.010 | 0.276 | 0.212 | 79.62 ± 1.11, 1.0 | 3.17 |
| | | 0.0005 | 0.105 ± 0.005 | 0.120 | 0.090 | 126.77 ± 1.06, 0.1 | 0.80 |
| DBX-1 | T = 12 m | 0.001 | 0.228 ± 0.014 | 0.272 | 0.183 | 80.74 ± 1.08, 1.0 | 3.26 |
| | aged | 0.0005 | 0.106 ± 0.007 | 0.127 | 0.086 | 138.23 ± 1.10, 0.1 | 0.96 |
| DBX-1 | T = 12 m | 0.001 | 0.246 ± 0.028 | 0.332 | 0.160 | 85.31 ± 1.01, 1.0 | 3.64 |
| | unaged | 0.0005 | 0.110 ± 0.007 | 0.131 | 0.090 | 130.32 ± 1.09, 0.1 | 0.85 |

Each data value is generated from a 30 unit Bruceton analysis to give a mean energy value required for initiation. Constant current initiation testing utilized an appropriate current applied for 10 seconds in 10 mA steps, while capacitor discharge tests utilized either a 0.1 microfarad (160-180 volts) or 1.0 mfd (80-100 volts) capacitor and 0.3 log unit voltage steps.

Evaluation of the data indicates that under constant current conditions, the energy required to initiate DBX-1 from a hot-wire is slightly less than that required for RD1333. Using a capacitive discharge pulse, the energy required to sustain ignition of both materials is quite similar. In certain embodiments, the type of power supplied to the bridgewire may be in the form of constant current or current voltage, as well as output from a capacitor discharge.

In addition to the testing above, DBX-1 may be used in hot-wire applications to initiate a variety of explosive output compositions. Specifically, DBX-1 may be used to ignite output compositions including explosives, pyrotechnics, and propellants. Examples of explosives include but are not limited to octahydro-1,3,5,7-tetranitro-1,3,5,7-tetrazocine (“HMX”), cyclotrimethylenetrinitramine (“RDX”), 2,6-Bis(Picrylamino)-3,5-dinitropyridine (“PYX”), 2,4,6-trinitrotoluene (“TNT”), other secondary explosives, or other similar compounds.

The foregoing is provided for purposes of illustrating, explaining, and describing embodiments of the present invention. Modifications and adaptations to these embodiments will be apparent to those skilled in the art and may be made without departing from the scope or spirit of the invention.

That which is claimed is:

1. A hot-wire igniter device comprising:
(a) a bridgewire;
(b) an acceptor proximate a portion of the bridgewire and comprising copper(I) 5-nitrotetrazole; and
(c) an output configured to be ignited by the acceptor.

2. The hot-wire igniter device of claim 1, wherein the copper(I) 5-nitrotetrazole is substituted in place of normal lead styphnate, basic lead styphnate, zirconium/potassium perchlorate, or lead azide.

3. The hot-wire igniter device of claim 1, wherein the acceptor is free of lead.

4. The hot-wire igniter device of claim 1, wherein the bridgewire comprises Tophet A, Tophet C, stainless steel, nichrome bridgewire materials, or stablohm bridgewire materials.

5. The hot-wire igniter device of claim 1, wherein the bridgewire is configured to receive power from a power source.

6. The hot-wire igniter device of claim 5, wherein the power comprises a constant current or a constant voltage.

7. The hot-wire igniter device of claim 5, wherein the power source is a capacitor discharge.

8. The hot-wire igniter device of claim 1, wherein the output is an explosive, pyrotechnic, or propellant.

9. The hot-wire igniter device of claim 1, wherein the output comprises octahydro-1,3,5,7-tetranitro-1,3,5,7-tetrazocine, cyclotrimethylenetrinitramine, 2,6-Bis(Picrylamino)-3,5-dinitropyridine, or 2,4,6-trinitrotoluene.

10. An acceptor comprising copper(I) 5-nitrotetrazole, wherein the acceptor is configured for use in a hot-wire igniter device.

11. The acceptor of claim 10, wherein the copper(I) 5-nitrotetrazole is substituted in place of normal lead styphnate, basic lead styphnate, zirconium/potassium perchlorate, or lead azide.

12. The acceptor of claim 10, wherein the acceptor is configured to ignite an output.

13. The acceptor of claim 12, wherein the output comprises octahydro-1,3,5,7-tetranitro-1,3,5,7-tetrazocine, cyclotrimethylenetrinitramine, 2,6-Bis(Picrylamino)-3,5-dinitropyridine, or 2,4,6-trinitrotoluene.

14. A method of preparing a hot-wire igniter device having a bridgewire, an acceptor, and an output comprising:
(a) positioning the acceptor proximate the bridgewire, wherein the acceptor comprises copper(I) 5-nitrotetrazole; and
(b) positioning the output proximate the acceptor.

15. The method of claim 14, further comprising:
(c) substituting copper(I) 5-nitrotetrazole in place of normal lead styphnate, basic lead styphnate, zirconium/potassium perchlorate, or lead azide.

16. The method of claim 14, wherein the acceptor is free of lead.

17. The method of claim 14, wherein the bridgewire comprises Tophet A, Tophet C, stainless steel, nichrome bridgewire materials, or stablohm bridgewire materials.

18. The method of claim 14, further comprising:
(c) supplying power to the bridgewire.

19. The method of claim 18, wherein the power comprises a constant current or a constant voltage.

20. The method of claim 18, wherein the power is supplied by a capacitor discharge.

21. The method of claim 14, wherein the output is an explosive, pyrotechnic, or propellant.

22. The method of claim 14, wherein the output comprises octahydro-1,3,5,7-tetranitro-1,3,5,7-tetrazocine, cyclotrimethylenetrinitramine, 2,6-Bis(Picrylamino)-3,5-dinitropyridine, or 2,4,6-trinitrotoluene.
